(19) United States
(12) Patent Application Publication
(10) Pub. No.: US 2012/0032155 A1
(43) Pub. Date: Feb. 9, 2012

(54) LIGHT-EMITTING ELEMENT, LIGHT-EMITTING DEVICE, DISPLAY DEVICE, AND ELECTRONIC APPARATUS

(75) Inventor: Masayuki MITSUYA, Suwa-shi (JP)

(73) Assignee: SEIKO EPSON CORPORATION, Tokyo (JP)

(21) Appl. No.: 13/197,134

(22) Filed: Aug. 3, 2011

(30) Foreign Application Priority Data
Aug. 5, 2010 (JP) 2010-176636

(51) Int. Cl. H01L 51/52

(52) U.S. Cl. 257/40; 257/E51.018

(57) ABSTRACT

A light-emitting element includes an anode; a cathode; a first light-emitting layer that is disposed between the anode and the cathode, the first light-emitting layer emitting light in response to application of voltage between the anode and the cathode; a second light-emitting layer that is disposed between the cathode and the first light-emitting layer, the second light-emitting layer emitting light in response to application of voltage between the anode and the cathode; and a carrier-generating layer that is disposed between the first light-emitting layer and the second light-emitting layer, the carrier-generating layer generating electrons and holes. The carrier-generating layer has an n-type electron transport layer and an electron-withdrawing layer, the n-type electron transport layer contacting the first light-emitting layer and having electron transportability, and the electron-withdrawing layer being disposed between the n-type electron transport layer and the second light-emitting layer and having electron-withdrawing properties.

### BACKGROUND

1. Technical Field

The present invention relates to a light-emitting element, light-emitting device, display device, and electronic apparatus.

2. Related Art

An organic electroluminescence device (namely, organic EL device) is a light-emitting element having a configuration in which at least one organic light-emitting layer is disposed between an anode and a cathode. In such a light-emitting element, an electric field is applied between the cathode and anode with the result that electrons are injected from the cathode to the light-emitting layer and that holes are injected from the anode to the light-emitting layer. The electrons then recombine with the holes in the light-emitting layer with the result that the excitons are generated. The excitons return to a ground state and thereby generate energy, and the energy is released in the form of light.

One of a typical type of such a device has, for example, a configuration in which two or more light-emitting elements are disposed between a cathode and an anode and in which a charge-generating layer (career-generating layer) is provided between the light-emitting layers (see, JP-A-2007-59848, for example).

In such a light-emitting element, an electric field is applied between the anode and the cathode with the result that electrons and holes are generated in the charge-generating layer and are then supplied to each of the light-emitting layer. In addition to holes and electrons that are respectively supplied from the anode and cathode, the electrons and holes that are supplied from the charge-generating layer can be accordingly utilized to emit light from each of the light-emitting layers. Such a light-emitting element can emit light with high luminance and has excellent light emission efficiency as compared with the light-emitting element having a single light-emitting layer. In addition, even in the case where such a light-emitting element is used at a low current level, the light-emitting element can emit light with relatively high luminance as compared with the light-emitting element having a single light-emitting layer, and the quality of such a light-emitting element is therefore less likely to be degraded. Long emission lifetime can be accordingly provided.

Unfortunately, traditional light-emitting elements have a problem in which the devices are continuously driven at a constant current level with the result that a driving voltage is significantly increased with the passage of time.

### SUMMARY

An advantage of some aspects of the invention is that it provides a light-emitting element in which the increase of a driving voltage can be suppressed even in the case of continuous driving at a constant current level, a light-emitting device including such a light-emitting element, a display device, and an electronic apparatus.

In order to provide such an advantage, according to a first aspect of the invention, there is provided a light-emitting element including: an anode, a cathode, a first light-emitting layer that is disposed between the anode and the cathode, the first light-emitting layer emitting light in response to application of voltage between the anode and the cathode; a second light-emitting layer that is disposed between the cathode and the first light-emitting layer, the second light-emitting layer emitting light in response to application of voltage between the anode and the cathode; and a carrier-generating layer that is disposed between the first light-emitting layer and the second light-emitting layer, the carrier-generating layer generating electrons and holes. The carrier-generating layer has an n-type electron transport layer and an electron-withdrawing layer, the re-type electron transport layer contacting the first light-emitting layer and having electron transportability, and the electron-withdrawing layer being disposed between the n-type electron transport layer and the second light-emitting layer and having electron-withdrawing properties.

In the light-emitting element having such an advantageous configuration, because the n-type electron transport layer of the carrier-generating layer contacts the first light-emitting layer, diffusion of the material used for the n-type electron transport layer (electron donor material, especially) to the anode-side layer (namely, the first light-emitting layer) can be prevented or suppressed. Even if the light-emitting element is continuously driven at a constant current level for long time, the electron transportability and electron injection properties of the re-type electron transport layer can be therefore prevented from being decreased. The increase of the driving voltage of the light-emitting element can be accordingly suppressed.

In the light-emitting element having such an advantageous configuration, it is preferable that the first light-emitting layer has an average thickness that is in the range from 30 to 100 nm.

By virtue of such a configuration, even if the material (electron donor material) used for the n-type electron transport layer of the carrier-generating layer diffuses to the first light-emitting layer, the light-emitting properties of the first light-emitting layer can be kept in good condition. In addition, the thickness of the first-light emitting layer is prevented from being excessively increased, and the initial driving voltage of the light-emitting element can be therefore prevented from being increased.

In the light-emitting element having such advantageous configurations, it is preferable that the n-type electron transport layer is formed by using a mixed material containing an electron transportable material and an electron donor material.

The n-type electron transport layer that is formed in this manner has excellent electron transportability and electron injection properties. The electrons generated in the carrier-generating layer can be therefore efficiently transported to and injected into the first light-emitting layer.

In the light-emitting element having such advantageous configurations, it is preferable that the concentration of the electron donor material contained in the n-type electron transport layer is gradually decreased from the side of the cathode to the side of the anode.

By virtue of such a configuration, the electrons generated in the carrier-generating layer can be efficiently transported to and injected into the first light-emitting layer, and an amount in which the donor material diffuses from the n-type transport layer to the first light-emitting layer can be reduced, thereby being able to prolong the lifetime of the light-emitting element.

In the light-emitting element having such advantageous configurations, it is preferable that the electron donor material contains at least one of the alkali metal, alkali earth metal, an alkali metal compound, and an alkali earth metal compound.

Such an electron donor material has excellent electron injection properties. The electrons generated in the carrier-generating layer can be therefore efficiently transported to and injected into the first light-emitting layer.

In the light-emitting element having such advantageous configurations, it is preferable that the first light-emitting layer contains a light-emitting material which generates fluorescence in response to application of voltage between the anode and the cathode.

A light-emitting material which generates phosphorescence (phosphorescent material) has excellent light-emitting efficiency relative to that of the light-emitting material which generates fluorescence (fluorescent material). The phosphorescent material is, however, sensitive to impurities in the change of light-emitting properties. In the case where impurities content is changed with continuous driving of the light-emitting element, the light-emitting properties vary. The fluorescent material is insensitive to impurities in the change of light-emitting properties as compared with the phosphorescent material and is accordingly used as the light-emitting material of the first light-emitting layer, so that the change in the light-emitting properties of the first light-emitting layer can be suppressed even if the material used for the n-type electron transport layer diffuses to the first light-emitting layer in association with the continuous driving of the light-emitting element.

In the light-emitting element having such advantageous configurations, it is preferable that the second light-emitting layer contains a light-emitting material which generates phosphorescence in response to application of voltage between the anode and the cathode.

The phosphorescent material is used as the light-emitting material of the second light-emitting layer in which impurities do not diffuse or are less likely to diffuse in association with continuous driving of the light-emitting element, so that the second light-emitting layer efficiently emits light. The light-emitting properties of the light-emitting element can be accordingly enhanced.

In the light-emitting element having such advantageous configurations, it is preferable that the second light-emitting layer emits light having a peak wavelength longer than the peak wavelength of light emitted from the first light-emitting layer.

By virtue of such an advantageous configuration, the first light-emitting layer and second light-emitting layer can emit light in a balanced manner.

The light-emitting element having such advantageous configurations preferably includes a third light-emitting layer that is disposed between the second light-emitting layer and the cathode, the third light-emitting layer emitting light in response to application of voltage between the anode and the cathode.

By virtue of such a configuration, the first light-emitting layer, second light-emitting layer, and third light-emitting layer can emit light in a balanced manner. Furthermore, these light emitting-layers are configured, for example, so as to individually emit light beams of red, green, and blue, thereby being able to provide a light-emitting element that emits white light.

In the light-emitting element having such advantageous configurations, it is preferable that the third light-emitting layer contains a light-emitting material which generates phosphorescence in response to application of voltage between the anode and the cathode.

In such a configuration, the phosphorescent material is used as the light-emitting material of the third light-emitting layer in which impurities do not diffuse or are less likely to diffuse, so that the third light-emitting layer efficiently emits light. The light-emitting properties of the light-emitting element can be accordingly enhanced.

In the light-emitting element having such advantageous configurations, it is preferable that the third light-emitting layer emits light having a peak wavelength longer than the peak wavelength of light emitted from the first light-emitting layer.

By virtue of such a configuration, the first light-emitting layer, second light-emitting layer, and third light-emitting layer can emit light in a balanced manner.

In the light-emitting element having such advantageous configurations, it is preferable that the electron-withdrawing layer contains organic cyanide having an aromatic ring.

The aromatic ring-containing organic cyanide has excellent electron-withdrawing properties. The electron-withdrawing layer which is formed so as to contain the organic cyanide having an aromatic ring can therefore contribute to generating electrons and holes in the carrier-generating layer in a large amount.

In the light-emitting element having such advantageous configurations, it is preferable that the organic cyanide is a hexaazatriphenylene derivative.

Such a compound has excellent electron-withdrawing properties. The electron-withdrawing layer that is formed so as to contain such a compound can therefore sufficiently withdraw electrons from an adjacent layer and can desirably transport the withdrawn electrons to the side of the anode.

According to a second aspect of the invention, there is provided a light-emitting device including the light-emitting element having any of the above advantages.

By virtue of such a configuration, the increase of a driving voltage can be suppressed even in the case of driving at a constant current level for long time.

According to a third aspect of the invention, there is provided a display device including the light-emitting device having such an advantageous configuration.

By virtue of such a configuration, a display device which can be stably driven and which exhibits high reliability can be provided.

According to a fourth aspect of the invention, there is provided an electronic apparatus including the display device having such an advantageous configuration.

By virtue of such a configuration, an electronic apparatus which exhibits high reliability can be provided.

### BRIEF DESCRIPTION OF THE DRAWINGS

The invention will be described with reference to the accompanying drawings, wherein like numbers reference like elements.

FIG. 1 is a longitudinal sectional view schematically illustrating a light-emitting element of a preferred embodiment of the invention.

FIG. 2 is a longitudinal sectional view illustrating a display to which the display device of embodiments of the invention is applied.

FIG. 3 is a perspective view illustrating the configuration of a mobile (or laptop) personal computer to which an electronic apparatus of embodiments of the invention is applied.

FIG. 4 is a perspective view illustrating the configuration of a mobile phone [including Personal Handyphone System (PHS)] to which the electronic apparatus of embodiments of the invention is applied.

FIG. 5 is a perspective view illustrating the configuration of a digital still camera to which the electronic apparatus of embodiments of the invention is applied.

FIG. 6 is a graph illustrating relationships between a driving voltage and time in light-emitting elements of specific examples of embodiments of the invention.

### DESCRIPTION OF EXEMPLARY EMBODIMENTS

Preferred embodiments of the light-emitting element, display device, and electronic apparatus of embodiments of the invention will be hereinafter described with reference to the accompanying drawings.

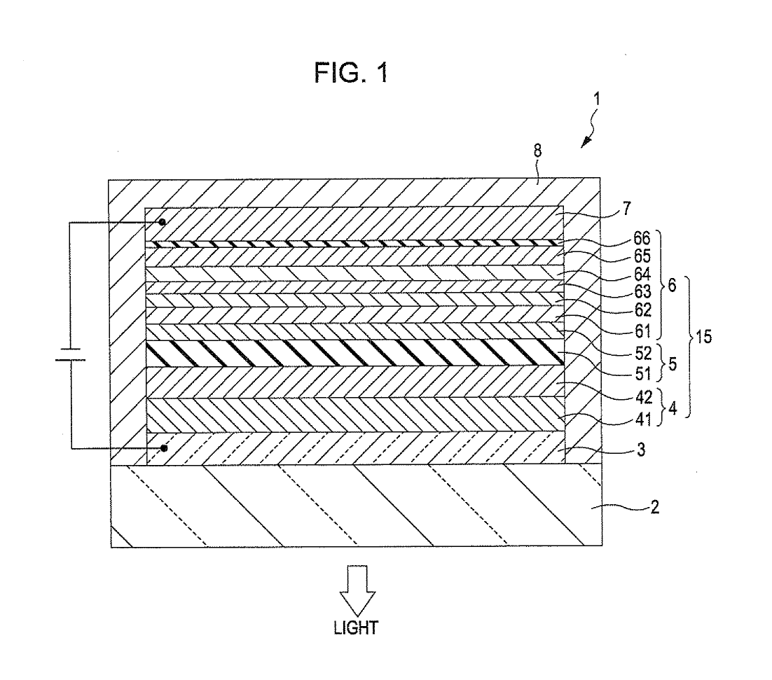

FIG. 1 is a longitudinal sectional view schematically illustrating a light-emitting element of a preferred embodiment of the invention. For convenience of illustration, the top of FIG. 1 is referred to as the “top” of the device, whereas the bottom of FIG. 1 is referred to as the “bottom” of the device.

A light-emitting element (electroluminescence device) 1 includes an anode 3, a first light emitter (first light-emitting unit) 4, a carrier-generating layer 5, a second light emitter (second light-emitting unit) 6, and a cathode 7, each being stacked in sequence.

In other words, the light-emitting element 1 has configurations in which the first light emitter 4, carrier-generating layer 5, and second light emitter 6 are stacked in sequence to form a layered structure 15 and in which the layered structure 15 is disposed between the two electrodes (anode 3 and cathode 7).

The first light emitter 4 has a configuration in which a hole transport layer 41 and a first light-emitting layer 42 are stacked in sequence from the side of the anode 3 to the side of the cathode 7 to form a layered structure. The second light emitter 6 has a configuration in which a hole transport layer 61, a second light-emitting layer 62, a third light-emitting layer 63, a hole-blocking layer 64, an electron transport layer 65, and an electron injection layer 66 are stacked in sequence from the side of the anode 3 to the side of the cathode 7 to form a layered structure.

The light-emitting element 1 is entirely provided on a substrate 2 and sealed with a sealing member 8.

In the light-emitting element 1, a driving voltage is applied between the anode 3 and the cathode 7, thereby generating carriers (electrons and holes) in the carrier-generating layer 5. Holes are supplied (injected) from the anode 3 to the first light-emitting layer 42, and electrons are supplied from the carrier-generating layer 5 to the first light emitting layer 42. Electrons are supplied (injected) from the cathode 7 to the second and third light-emitting layers 62 and 63, and holes are supplied from the carrier-generating layer 5 to the second and third light-emitting layers 62 and 63. In each of the light-emitting layers, the holes and the electrons recombine with the result that energy is released, and excitons are generated by the released energy. Energy (fluorescence or phosphorescence) is then released (light emission) when the excitons return to a ground state.

Through these processes, each of the first light-emitting layer 42, second light-emitting layer 62, and third light-emitting layer 63 can emit light. In the light-emitting element 1, light emission efficiency can be consequently enhanced, and a driving voltage can be reduced, as compared with a light-emitting element merely having a single light-emitting layer.

Furthermore, in the light-emitting element 1, for example, the light-emitting layers are configured so as to individually emit red light, green light, and blue light, thereby providing a light-emitting element which emits white light.

The substrate 2 supports the anode 3. The light-emitting element 1 of this embodiment has a configuration in which light is emitted from the side of the substrate 2 (bottom emission type). The substrate 2 and the anode 3 are therefore configured so as to be substantially transparent (colorless transparent, colored transparent, or semi-transparent).

Examples of a material of the substrate 2 include a resin material such as polyethylene terephthalate, polyethylene naphthalate, polypropylene, cycloolefin polymer, polyamide, polyether sulfone, polymethylmethacrylate, polycarbonate, or polyarylate; and a glass material such as quartz glass or soda glass. These materials may be used alone or in combination of two or more.

Although the average thickness of the substrate 2 is not specifically limited, the substrate 2 has an average thickness that is preferably in the approximate range from 0.1 to 30 mm, more preferably in the approximate range from 0.1 to 10 mm.

In the case where the light-emitting element 1 has a configuration in which light is emitted from the opposite side of the substrate 2 (top emission type), either a transparent or nontransparent substrate may be used.

Examples of the nontransparent substrate include a substrate made from a ceramic material such as alumina; a metallic substrate, such as a stainless steel substrate, on which an oxide film (insulating film) is formed on a surface thereof; and a substrate made from a resin material.

Components of the light-emitting element 1 will be hereinafter described in series.

### Anode

The anode 3 injects holes into the first light emitter 4 that will be hereinafter described. A material having a large work function and excellent electric conductivity is preferably used as a material of the anode 3.

Examples of the material of the anode 3 include oxides such as indium tin oxide (ITO), indium zinc oxide (IZO), In₃O₃, SnO₂, Sb-containing SnO₂, and Al-containing ZnO; Au; Pt; Ag; Cu; and an alloy thereof. These materials may be used alone or in combination of two or more.

Although the average thickness of the anode 3 is not specifically limited, the anode 3 has an average thickness that is preferably in the range from 10 to 200 nm, more preferably in the range from 50 to 150 nm.

### First Light Emitter

As described above, the first light emitter 4 has the hole transport layer 41 and the first light-emitting layer 42.

### Hole Transport Layer

The hole transport layer 41 has a function to transport the holes injected from the anode 3 to the first light-emitting layer 42.

As the material of the hole transport layer 41, various high-molecular-weight p-type materials or various low-molecular-weight p-type materials can be used alone or in combination. Examples of such materials include tetraarylbenzidine derivatives such as N,N′-di-(1-naphthyl)-N,N′-diphenyl-1,1′-biphenyl-4,4′-diamine (NPD) and N,N′-diphenyl-N,N′-bis(3-methylphenyl)-(1,1′-biphenyl)-4,4′-diamine (TPD) and includes tetraaryldiaminofluorenes and derivatives thereof (amine compounds). These materials may be used alone or in combination of two or more.

In particular, the hole transport material preferably has a benzidine structure, and tetraarylbenzidines or derivatives thereof are more preferably employed. Owing to use of such a material, holes can be efficiently injected from the anode 3 into the hole transport layer 41 and can be then efficiently transported to the first light-emitting layer 42.

Although the average thickness of the hole transport layer 41 is not specifically limited, the hole transport layer 41 has an average thickness that is preferably in the range from 10 to 150 nm, more preferably in the range from 10 to 100 nm.

### First Light-Emitting Layer

The first light-emitting layer 42 contains a light-emitting material.

The light-emitting material receives electrons that are supplied (injected) from the layer on the side of the cathode 7 and receives the holes that are supplied (injected) from the layer on the side of the anode 3. The holes and the electrons then recombine with the result that energy is released, and excitons are generated by the released energy. Energy (fluorescence or phosphorescence) is released (light emission) when the excitons return to a ground state.

Such a light-emitting material is not specifically limited, and various fluorescent materials and various phosphorescent materials may be used alone or in combination of two or more.

Examples of a red fluorescent material include perylene derivatives such as tetraaryldiindenoperylene derivatives, europium complexes, benzopyran derivatives, rhodamine derivatives, benzothioxanthene derivatives, porphyrin derivatives, vile red, 2-(1,1-dimethylethyl)-6-(2-(2,3,6,7-tetrahydro-1,1,7,7-tetramethyl-1H,5H-benzo(ij)quinolizin-9-yl)ethenyl)-4H-pyran-4H-ylidene)propanedinitrile (DCJTB), and 4-(dicyanomethylene)-2-methyl-6-(p-dimethylaminostyryl)-4H-pyran (DCM).

Examples of a blue fluorescent material include distyryldiamine derivatives, distyryl derivatives, fluoranthene derivatives, pyrene derivatives, perylene and derivatives thereof, anthracene derivatives, benzoxazole derivatives, benzothiazole derivatives, benzimidazole derivatives, chrysene derivatives, phenanthrene derivatives, distyrylbenzene derivatives, tetraphenylbutadiene, 4,4′-bis(9-ethyl-3-carbazovinylene)-1,1′-biphenyl (BCzVBi), poly[(9,9-dioctylfluorene-2,7-diyl)-co-(2,5-dimethoxybenzene-1,4-diyl)], poly[(9,9-dihexyloxyfluorene-2,7-diyl)-ortho-co-(2-methoxy-5-{2-ethoxyhexyloxy}phenylene-1,4-diyl)], poly[(9,9-dioctylfluorene-2,7-diyl)-co-(ethynylbenzene)], and BD102 (the name of a product commercially available from Idemitsu Kosan Co., Ltd.).

Examples of a green fluorescent material include coumarin derivatives, quinacridone derivatives, 9,10-bis[(9-ethyl-3-carbazolyl)-vinylenyl]-anthracene, poly(9,9-dihexyl-2,7-vinylenefluorenylene), poly[(9,9-dioctylfluorene-2,7-diyl)-co-(1,4-diphenylene-vinylene-2-methoxy-5-{2-ethylhexyloxy}benzene)], and poly[(9,9-dioctyl-2,7-divinylenefluorenylene)-ortho-co-(2-methoxy-5-(2-ethoxylhexyloxy)-1,4-phenylene)].

Examples of a yellow fluorescent material include compounds, such as rubrene materials, having a naphthacene skeleton which contains an aryl group (phenyl group, preferably) in appropriate sites and numbers (two to six, preferably) and includes mono-indenoperylene derivatives.

Examples of a red phosphorescent materials include metal complexes such as those of Ir, Ru, Pt, Os, Re, or Pd. At least one of the ligands of these metal complexes may have a phenylpyridine skeleton, a bipyridyl skeleton, or a porphyrin skeleton. Specific examples of such a material include tris(1-phenylisoquinoline)iridium [Ir(piq)₃] represented by the following formula 1, bis[2-(2′-benzo[4,5-α]thienyl) pyridinato-N,C³′]iridium(acetylacetonate) [btp2Ir(acac)], 2,3,7,8,12,13,17,18-octaethyl-12H,23H-porphyrin-platinum(II), bis[2-(2 benzo[4,5-a]thienyl)pyridinato-N,C³′]iridium, and bis(2-phenylpyridine)iridium(acetylacetonate).

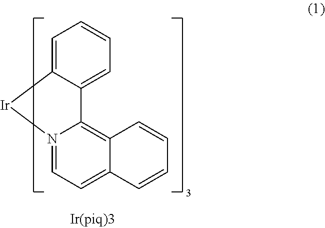

Examples of a blue phosphorescent material include metal complexes such as those of Ir, Ru, Pt, Os, Re, and Pd. Specific examples of such a material include bis[4,6-difluorophenylpyridinato-N,C²′]-picolinate-iridium, tris[2-(2,4-difluorophenyl)pyridinato-N,C²′]iridium, bis[2-(3,5-trifluoromethyl)pyridinato-N,C²′]-picolinate-iridium, and bis(4,6-difluorophenylpyridinato-N,C²′)iridium(acetylacetonate).

Examples of a green phosphorescent material include metal complexes such as those of Ir, Ru, Pt, Os, Re, or Pd. In particular, at least one of the ligands of these metal complexes may have a phenylpyridine skeleton, a bipyridyl skeleton, or a porphyrin skeleton. Specific examples of such a material include fac-tris(2-phenylpyridine)iridium [Ir(ppy)₃] represented by the following formula 2, bis(2-phenylpyridinato-N,C²′)iridium(acetylacetonate), and fac-tris[5-fluoro-2-(5-trifluoromethyl-2-pyridine)phenyl-C,N]iridium.

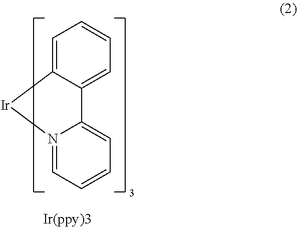

In addition to the light-emitting material, the first light-emitting layer 42 may contain a material which serves as a host material with respect to the light-emitting material which functions as a guest material. For example, the host material is doped with the light-emitting material as the guest material which serves as the dopant, thereby being able to form the first light-emitting layer 42.

The host material functions to recombine electrons with holes to generate excitons and functions to transfer the energy of the excitons to the light-emitting material (Forster transfer or Dexter transfer) to excite the light-emitting material.

In the case where the light-emitting material contains a fluorescent material, examples of the host material include, but are not limited to, rubrene and derivatives thereof, distyrylarylene derivatives, naphthacene materials such as bis(p-biphenyl naphthacene), anthracene materials, perylene derivatives such as bis-ortho biphenylyl perylene, pyrene derivatives such as tetraphenylpyrene, distyrylbenzene derivatives, stilbene derivatives, distyrylamine derivatives, quinolinolato metal complexes such as a bis(2-methyl-8-quinolinolato)(p-phenyl phenolato)aluminum complex (BAlq) and a tris(8-quinolinolato)aluminum complex (ALq₃), triarylamine derivatives such as triphenylamine tetramer, arylamine derivatives, oxadiazole derivatives, silole derivatives, carbazole derivatives, oligothiophene derivatives, benzopyran derivatives, triazole derivatives, benzoxazole derivatives, benzothiazole derivatives, quinoline derivatives, coronene derivatives, amine compounds, 4,4′-bis(2,2′-diphenylvinyl)biphenyl (DPVBi), and IDE 120 (the name of a product commercially available from Idemitsu Kosan Co., Ltd.). These materials may be used alone or in combination of two or more. In the case of using a blue or green light-emitting material, IDE 120, the anthracene materials, or dianthracene materials are preferably employed. In the case of using a red light-emitting material, rubrene, rubrene derivatives, naphthacene materials, or perylene derivatives are preferably employed.

In the case where the light-emitting material contains a phosphoscent material, examples of the host material include carbazole derivatives such as 3-phenyl-4-(l′-naphthyl)-5-phenylcarbazole and 4,4′-N,N′-dicarbazolebiphenyl (CBP) represented by the following formula 3; phenanthroline derivatives; triazole derivatives; tris(8-quinolinolato)aluminum (Alq); quinolinolato metal complexes such as bis-(2-methyl-8-quinolinolato)-4-(phenylphenolato)aluminum; carbazolyl group-containing compounds such as N-dicarbazolyl-3,5-benzene, poly(9-vinylcarbazole), 4,4′,4″-tris(9-carbazolyl)triphenylamine, and 4,4′-bis(9-carbazolyl)-2,2′-dimethyl biphenyl; and 2,9-dimethyl-4,7-diphenyl-1,10-phenanthroline (BCP). These materials may be alone or in combination of two or more.

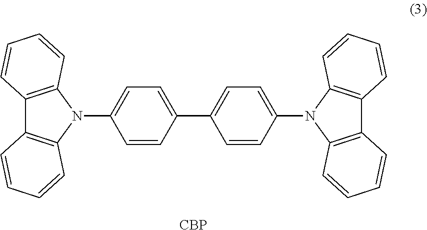

In the case where the host material is used in combination with the light-emitting material (guest material), the light-emitting material is contained in the first light-emitting layer 42 in an amount (dosage) that is preferably in the range from 0.1 to 30 weight %, more preferably in the range from 0.5 to 20 weight %. The content of the light-emitting material is determined so as to fall within the above ranges, thereby being able to optimize the light emission efficiency.

Fluorescent materials are preferably employed as the light-emitting material of the first light-emitting layer 42. In other words, the first light-emitting layer 42 preferably contains a light-emitting material that generates fluorescence in response to application of voltage between the anode 3 and the cathode 7.

The light-emitting material (phosphorescent material) that generates phosphorescence has excellent light emission efficiency as compared with the light-emitting material (fluorescent material) that generates fluorescence. The phosphorescent material is, however, sensitive to impurities in the change of light-emitting properties. In the case where impurities content changes in association with continuous driving of the light-emitting element, the light-emitting properties therefore vary. The fluorescent material, which is insensitive to impurities in the change of light-emitting properties as compared with the phosphorescent material, is accordingly used as the light-emitting material of the first light-emitting layer 42, so that the change of the light-emitting properties of the first light-emitting layer 42 can be suppressed even if the material of an n-type electron transport layer 51 diffuses to the first light-emitting layer 42 in association with continuous driving of the light-emitting element 1.

The light emitted from the first light-emitting layer 42 preferably has a peak wavelength shorter than that of the light emitted from the second light-emitting layer 62 that will be hereinafter described. In other words, the light emitted from the second light-emitting layer 62 preferably has a peak wavelength longer than that of the light emitted from the first light-emitting layer 42. By virtue of such a configuration, the first light-emitting layer 42 and the second light-emitting layer 62 can emit light in a balanced manner.

The light emitted from the first light-emitting layer 42 preferably has a emission peak wavelength of 500 nm or shorter, more preferably in the range from 400 to 490 nm, and further preferably in the range from 430 to 480 nm. In other words, the first light-emitting layer 42 emits blue light.

The light-emitting material which serves to emit light exhibiting a short peak wavelength has difficulty in light emission as compared with the light-emitting material which serves to emit light exhibiting a long peak wavelength. In the first light-emitting layer 42 which is positioned so as not to be adjacent to other light-emitting layers, however, energy is less likely to be released to other light-emitting layers even in the case of using the light-emitting material which serves to emit light exhibiting a short peak wavelength, and light can be therefore efficiently emitted.

The first light-emitting layer 42 has an average thickness that is preferably in the range from 30 to 100 nm, more preferably in the range from 30 to 70 nm, further preferably in the range from 30 to 50 nm. Within such ranges, even if the material (electron donor material, especially) used for the n-type electron transport layer 51 of the carrier-generating layer 5 that will be hereinafter described diffuses to the first light-emitting layer 42, the light-emitting properties of the first light-emitting layer 42 can be kept in good condition. In addition, the thickness of the first light-emitting layer 42 can be prevented from being excessively increased, and the initial driving voltage of the light-emitting element 1 can be therefore prevented from being increased. In other words, the driving voltage of the light-emitting element 1 can be decreased.

In contrast, in the case where the first light-emitting layer 42 has an average thickness below the lower limits of such ranges, for example depending on the concentration of the electron donor material adjacent to the interface between the n-type electron transport layer 51 and the first light-emitting layer 42, the light-emitting properties of the first light-emitting layer 42 may be decreased as a result of being affected by the electron donor material which has diffused from the n-type electron transport layer 51 to the first light-emitting layer 42. On the other hand, in the case where the first light-emitting layer 42 has an average thickness exceeding the upper limits of such ranges, the driving voltage of the light-emitting element 1 is likely to be increased.

In this embodiment, although description is made assuming that the first light emitter 4 includes a single light-emitting layer, the first light emitter 4 may have a layered structure in which a plurality of light-emitting layers are stacked. In this case, the light-emitting layers may individually emit light beams of the same or different colors. Furthermore, in the case where the first light emitter 4 has a plurality of the light-emitting layers, an intermediate layer may be provided between the light-emitting layers.

### Carrier-Generating Layer

The carrier-generating layer 5 has a function to generate carriers (holes and electrons).

The carrier-generating layer 5 has a configuration in which the n-type electron transport layer 51 and an electron-withdrawing layer 52 are stacked in sequence from the side of the anode 3 to the side of the cathode 7.

In the carrier-generating layer 5, because the n-type electron transport layer 51 contacts the first light-emitting layer 42, and the diffusion of the material (especially, electron donor material hereinafter described) of the n-type electron transport layer 51 to the layer on the side of the anode 3 (the first light-emitting layer 42 in this embodiment) can be prevented or suppressed. Even in the case where the light-emitting element 1 is continuously driven at a constant current level for long time, reduction in the electron transportability and electron injection properties of the n-type electron transport layer 51 is accordingly prevented. The increase of the driving voltage of the light-emitting element 1 can be consequently suppressed.

The carrier-generating layer 5 has an average thickness that is preferably in the range from 5 to 80 nm, more preferably in the range from 20 to 70 nm. Within such ranges, the driving voltage of the light-emitting element 1 can be prevented from being increased, and the function (carrier-generating function) of the carrier-generating layer 5 can be sufficiently fulfilled.

Each of the layers included in the carrier-generating layer 5 will be sequentially described in detail.

### Electron Transport Layer

The n-type electron transport layer 51 is provided between the first light-emitting layer 42 and the electron-withdrawing layer 52 and has a function to transport electrons from the electron-withdrawing layer 52 to the first light-emitting layer 42.

The n-type electron transport layer 51 contains an electron transportable material having electron transportability as a primary material and preferably contains an electron-injecting material (electron donor material) having electron injection properties in addition to the electron transportable material having electron transportability.

By virtue of such a configuration, electrons which have been withdrawn by the electron-withdrawing layer 52 can be efficiently injected into the n-type electron transport layer 51 and can be efficiently transported through the n-type electron transport layer 51 to the side of the anode 3.

In particular, the n-type electron transport layer 51 preferably contains a mixed material containing the electron transportable material and electron donor material. The n-type electron transport layer 51 having such composition has excellent electron transportability and electron injection properties. The electrons generated in the carrier-generating layer 5 can be therefore efficiently transported to and injected into the first light-emitting layer 42.

In the case where the electron donor material is added to the electron transportable material to form the re-type electron transport layer 51 (doping), the electron transportable material receives electron from the electron donor material in the n-type electron transport layer 51 and then enters a radical anion state. Carriers can be therefore generated in the carrier-generating layer 5 in an increased amount.

Examples of the electron transportable material used for the n-type electron transport layer 51 include quinoline derivatives such as organometallic complex containing 8-quinolinol or derivatives thereof as a ligand [for example, tris(8-quinolinolato)aluminum complex (ALq₃)], oxadiazole derivatives, perylene derivatives, pyridine derivatives, pyrimidine derivatives, quinoxaline derivatives, diphenylquinone derivatives, and nitro-substituted fluorene derivatives. These materials may be use alone or in combination of two or more.

Examples of the electron-injecting material (electron donor material) used for the n-type electron transport layer 51 include various types of inorganic insulating materials and various types of inorganic semiconductor materials.

Examples of the inorganic insulating materials include alkali metal chalcogenide (oxide, sulfide, selenide, or telluride), alkali earth metal chalcogenide, halide of alkali metal, and halide of alkali earth metal. These materials may be used alone or in combination of two or more.

Examples of the alkali metal chalcogenide include Li₂O, LiO, Na₂S, Na₂Se, and NaO.

Examples of the alkali earth metal chalcogenide include CaO, BaO, SrO, BeO, BaS, MgO, and CaSe.

Examples of the halide of alkali metal include CsF, LiF, NaF, KF, LiCl, KCl, and NaCl.

Examples of the halide of alkali earth metal include CaF₂, BaF₂, SrF₂, MgF₂, and BeF₂.

Examples of the inorganic semiconductor materials include oxides, nitrides, and oxynitrides, each containing at least one element selected from Li, Na, Ba, Ca, Sr, Yb, Al, Ga, In, Cd, Mg, Si, Ta, Sb, and Zn. These materials may be used alone or in combination of two or more.

In particular, as the electron-injecting material (electron donor material) used for the n-type electron transport layer 51, alkali metal, alkali earth metal, alkali metal compound, and alkali earth metal compound are preferably used alone or in combination of two or more. Owing to use of such a configuration, the n-type electron transport layer 51 has excellent electron transportability, and the electron injection properties of the n-type electron transport layer 51 can be further enhanced. In particular, the alkali metal compound (alkali metal chalcogenide, halide of alkali metal, or the like) has a significantly small work function, and such a material is used to form the n-type electron transport layer 51, so that the light-emitting element 1 emit light with high luminance.

Furthermore, the n-type electron transport layer 51 has a function of blocking holes.

In the case where the hole transportable material and electron-injecting material are used to form the n-type electron transport layer 51, the electron transportable material serves as a host material, the electron-injecting material serves as a guest material, and the electron transportable material is doped with the electron-injecting material through codeposition or the like, thereby being able to form the n-type electron transport layer 51.

In the case where the electron transportable material and electron-injecting material are used to form the n-type electron transport layer 51, the electron-injecting material is contained in the n-type electron transport layer 51 in an amount (dosage) that is preferably in the range from 0.1 to 20 weight %, more preferably in the range from 0.5 to 10 weight %. The electron-injecting material content falls within such ranges, thereby being able to excellently balancing the electron transportability and electron injection properties of the n-type electron transport layer 51.

Furthermore, in the case where the concentration of the electron donor material (electron-injecting material) in the n-type electron transport layer 51 is gradually reduced from the side of the cathode 7 to the side of the anode 3, the electrons generated in the carrier-generating layer 5 can be efficiently transported to and injected into the first light-emitting layer 42, and an amount in which the electron donor material in the n-type electron transport layer 51 diffuses to the first light-emitting layer 42 is reduced, thereby being able to prolong the lifetime of the light-emitting element 1. In this case, the concentration of the electric donor material may be gradually changed or may be successively changed.

Although the average thickness of the n-type electron transport layer 51 is not specifically limited, the n-type electron transport layer 51 has an average thickness that is preferably in the range from 10 to 100 nm, more preferably in the range from 10 to 50 nm. Within such ranges, electrons which have been withdrawn by the electron-withdrawing layer 52 can be efficiently transported to the side of the anode 3, and holes which have passed through the first light emitter 4 can be blocked.

### Electron-Withdrawing Layer

The electron-withdrawing layer (electron extraction layer) 52 is provided between the first light-emitting layer 42 and the second light-emitting layer 62 and has a function of withdrawing (extracting) electrons from the adjacent layer on the side of the cathode 7 (in this embodiment, the hole transport layer 61 of the second light emitter 6). The electrons which have been withdrawn by the electron-withdrawing layer 52 are injected into the adjacent layer on the side of the anode 3 (in the embodiment, the n-type electron transport layer 51).

The electron-withdrawing layer 52 contains an organic compound having electron-withdrawing properties as a primary component.

An organic cyanide having an aromatic ring (hereinafter referred to as “aromatic ring-containing organic cyanide”, where appropriate) is preferably used as the organic compound having electron-withdrawing properties.

The aromatic ring-containing organic cyanide has excellent electron-withdrawing properties. The electron-withdrawing layer 52 is formed so as to contain the aromatic ring-containing organic cyanide, thereby being able to generate holes and electrons in the carrier-generating layer 5 in an increased amount.

The electron-withdrawing layer 52 containing the aromatic ring-containing organic cyanide as a primary component contacts the adjacent layer (hole transport layer 61), thereby being able to withdraw electrons from the hole transportable material of the hole transport layer 61. In the case where the electron-withdrawing layer 52 contacts the hole transport layer 61 in a state in which a voltage is not applied, accordingly in the vicinity of the interface between the electron-withdrawing layer 52 and the hole transport layer 61, electrons are generated at the side of the electron-withdrawing layer 52, and holes are generated at the side of the hole transport layer 61. In such a state, in the case where a driving voltage is applied between the anode 3 and the cathode 7, the holes which have been generated in the vicinity of the interface between the electron-withdrawing layer 52 and the hole transport layer 61 are transported to the side of the cathode 7 on the basis of the driving voltage and contribute to light emission of the second light emitter 6 (specifically, the second light emitting layer 62 and the third light-emitting layer 63). In addition, the electrons which have been generated in the vicinity of the interface between the electron-withdrawing layer 52 and the hole transport layer 61 are transported to the side of the anode 3 on the basis of the driving voltage and contribute to light emission of the first light emitter 4 (specifically, the first light-emitting layer 42). Furthermore, holes and electrons are continuously generated owing to the function of the electron-withdrawing layer 52 during the application of the driving voltage as in the case described above, and the holes and electrons contribute to light emission of the first light-emitting layer 42, second light-emitting layer 62, and third light-emitting layer 63.

The aromatic ring-containing organic cyanide is a relatively stable compound and can be used to easily form the electron-withdrawing layer 52, for example, by a vapor deposition method. The aromatic ring-containing organic cyanide can be therefore preferably used to manufacture the light-emitting element 1, so that quality of the light-emitting element 1 to be manufactured becomes easily stabilized, and a yield of the light-emitting element 1 becomes increased.

Any aromatic ring-containing organic cyanide which functions as described above can be used, and preferable examples of such a compound include hexaazatriphenylene derivatives into which a cyano group is introduced, and the hexaazatriphenylene derivatives represented by the following formula 4 are more preferably used.

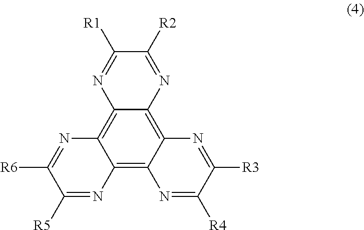

In the formula 4, R1 to R6 are each independently a cyano group (—CN), a sulfone group (—SO₂R′), a sulfoxide group (—SOR′), a sulfonamide group (—SO₂NR′₂), a sulfonate group (—SO₃R¹), a nitro group (—NO₂), or a trifluoromethane group (—CF₃), and at least one substituent among R¹ to R⁶ is a cyano group. R′ represents an alkyl group, an aryl group, or a heterocyclic group each having 1 to 60 carbon atoms and unsubstituted or substituted with an amine group, an amide group, an ether group, or an ester group.

Such a compound has excellent electron-withdrawing properties. The electron-withdrawing layer 52 which is formed by using such a compound can therefore sufficiently withdraw electrons from the adjacent layer (hole transport layer 61) and can desirably transfer the withdrawn electrons to the side of the anode 3.

In particular, in the aromatic ring-containing organic cyanide as the compound represented by the formula 4, R1 to R6 are each preferably a cyano group. Namely, hexacyanohexaazatriphenylene represented by the following formula 5 is preferably employed as the aromatic ring-containing organic cyanide. The compound represented by the formula 5 has a plurality of cyano groups having high electron-withdrawing properties. The electron-withdrawing layer 52 which is formed by using such a compound can therefore further sufficiently withdraw electrons from a material of the adjacent layer (hole transportable material of hole transport layer 61, for example) and can serve to increase an amount in which carriers (electrons and holes) are generated.

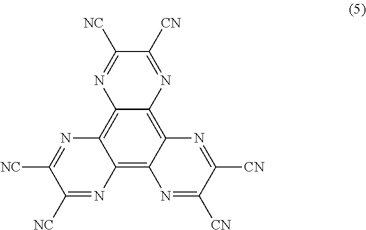

The aromatic ring-containing organic cyanide is preferably contained in the electron-withdrawing layer 52 so as to be in an amorphous state. Therefore, advantageous effect which is brought by the aromatic ring-containing organic cyanide as described above can be further efficiently provided.

The electron-withdrawing layer 52 has an average thickness that is preferably in the range from 5 to 40 nm, more preferably in the range from 10 to 30 nm. By virtue of such a configuration, the increase of a driving voltage of the light-emitting element 1 can be prevented, and the above function (electron-withdrawing properties) of the electron-withdrawing layer 52 can be sufficiently provided.

In the carrier-generating layer 5 having such a configuration, another layer may be provided between the n-type electron transport layer 51 and the electron-withdrawing layer 52. For example, a diffusion-preventing layer or an electron injection layer may be provided between the n-type electron transport layer 51 and the electron-withdrawing layer 52, the diffusion-preventing layer serving to prevent materials from diffusing between the n-type electron transport layer 51 and the electron-withdrawing layer 52, and the electron injection layer serving to inject electrons from the side of the electron-withdrawing layer 52 into the side of the n-type electron transport layer 51.

### Second Light Emitter

The second light emitter 6 includes the hole transport layer 61, the second light-emitting layer 62, the third light-emitting layer 63, the hole-blocking layer (intermediate layer) 64, the electron transport layer 65, and the electron injection layer 66.

### Hole Transport Layer

The hole transport layer 61 has a function to transport the holes injected from the carrier generation layer 5 (electron-withdrawing layer 52) to the second light-emitting layer 62. In addition, the hole transport layer 61 has a function to block electrons which have passed through the second light-emitting layer 62, thereby preventing the carrier-generating layer 5 from being impaired resulting from the arrival of the electrons at the carrier-generating layer 5.

In particular, the hole transport layer 61 is provided so as to be positioned between the second light-emitting layer 62 and the carrier-generating layer 5 and so as to contact the carrier-generating layer 5.

By virtue of such a configuration, the electron-withdrawing layer 52 can efficiently withdraw electrons from the hole transport layer 61 as described above. Holes and electrons can be therefore generated in the carrier-generating layer 5 in an increased amount.

The same material as used for the hole transport layer 41 can be employed as the material of the hole transport layer 61.

In particular, amine compounds are preferably employed as the hole transportable material used for the hole transport layer 61, and N,N′-di-(1-naphthyl)-N,N′-diphenyl-1,1′-biphenyl-4,4′-diamine (NPD) is more preferably employed. Such a compound contacts the carrier-generating layer 5 (electron-withdrawing layer 52) with the result that electrons are promptly withdrawn and that holes are then generated to be injected.

Although the average thickness of the hole transport layer 61 is not specifically limited, the hole transport layer 61 has an average thickness that is preferably in the range from 10 to 150 nm, more preferably in the range from 10 to 100 nm. By virtue of such a configuration, holes are desirably transported to the second light-emitting layer 62, and electrons that have passed through the second light-emitting layer 62 can be desirably blocked.

### Second Light-Emitting Layer

The second light-emitting layer 62 contains a light-emitting material.

Such a light-emitting material is not specifically limited, and the same material as used for the first light-emitting layer 42 can be employed. In this case, the light-emitting material used for the second light-emitting layer 62 may be the same as or different from the material used for the first light-emitting layer 42. In addition, the color of light to be emitted from the second light-emitting layer 62 may be the same as or different from the color of light to be emitted from the first light-emitting layer 42.

In addition to the light-emitting material, the second light-emitting layer 62 may contain a material which serves as a host material with respect to the light-emitting material which functions as a guest material.

In the case where the host material is used in combination with the light-emitting material (guest material), the light-emitting material is contained in the second light-emitting layer 62 in an amount (dosage) that is preferably in the range from 0.1 to 10 weight %, more preferably in the range from 0.5 to 5 weight %. The content of the light-emitting material is determined so as to fall within the above ranges, thereby being able to optimize the light emission efficiency.

Phosphorescent materials are preferably employed as the light-emitting material of the second light-emitting layer 62. In other words, the second light-emitting layer 62 preferably contains a light-emitting material that generates phosphorescence in response to application of voltage between the anode 3 and the cathode 7.

The phosphorescent material is used as the light-emitting material of the second light-emitting layer 62 in which impurities do not diffuse or are less likely to diffuse in association with continuous driving of the light-emitting element 1, so that the second light-emitting layer 62 efficiently emits light. The light emission efficiency of the light-emitting element 1 can be therefore enhanced.

The light emitted from the second light-emitting layer 62 preferably has a peak wavelength longer than the peak wavelength of the light emitted from the first light-emitting layer 42. The first light-emitting layer 42 and the second light-emitting layer 62 can therefore emit light in a balanced manner.

Although the average thickness of the second light-emitting layer 62 is not specifically limited, the second light-emitting layer 62 has an average thickness that is preferably in the range from 5 to 50 nm, more preferably in the range from 5 to 40 nm, and further preferably in the range from 5 to 30 nm. By virtue of such a configuration, the driving voltage of the light-emitting element 1 can be reduced, and the second light-emitting layer 62 can sufficiently emit light. In particular, in the case where the second light-emitting layer 62 and the third light-emitting layer 63 are stacked as in this embodiment, the second light-emitting layer 62 is configured so as to have a relatively thin thickness, so that both the second light-emitting layer 62 and the third light-emitting layer 63 are positioned in a recombination region in which holes and electrons recombine, thereby being able to emit light from these layers in a balanced manner.

### Third Light-Emitting Layer

The third light-emitting layer 63 contains a light-emitting material.

In this embodiment, the third light-emitting layer 63 contacts the second light-emitting layer 62. By virtue of such a configuration, both the second light-emitting layer 62 and the third light-emitting layer 63 are easily positioned in a recombination region of the second light emitter 6, in which holes and electrons recombine. Light can be therefore easily emitted from both the second light-emitting layer 62 and the third light-emitting layer 63.

Such a light-emitting material is not specifically limited, and the same light-emitting material used for the first light-emitting layer 42 can be employed. In this case, the light-emitting material used for the third light-emitting layer 63 may be the same as or different from the material used for the first light-emitting layer 42. In addition, the light-emitting material used for the third light-emitting layer 63 may be the same as or different from the material used for the second light-emitting layer 62. The color of light to be emitted from the third light-emitting layer 63 may be the same as or different from the color of light to be emitted from the first light-emitting layer 42. In addition, the color of light to be emitted from the third light-emitting layer 63 may be the same as or different from the color of light to be emitted from the second light-emitting layer 62.

In addition to the light-emitting material, the third light-emitting layer 63 may contain a material which serves as a host material with respect to the light-emitting material which functions as a guest material.

In the case where the host material is used in combination with the light-emitting material (guest material), the light-emitting material is contained in the third light-emitting layer 63 in an amount (dosage) that is preferably in the range from 0.1 to 30 weight %, more preferably in the range from 0.5 to 20 weight %. The content of the light-emitting material is determined so as to fall within the above ranges, thereby being able to optimize the light emission efficiency.

Phosphorescent materials are preferably employed as the light-emitting material of the third light-emitting layer 63. In other words, the third light-emitting layer 63 preferably contains a light-emitting material that generates phosphorescence in response to application of voltage between the anode 3 and the cathode 7.

The phosphorescent material is used as the light-emitting material of the third light-emitting layer 63 in which impurities do not diffuse or are less likely to diffuse in association with continuous driving of the light-emitting element 1, so that the third light-emitting layer 63 efficiently emits light. The light emission efficiency of the light-emitting element 1 can be therefore enhanced.

The light emitted from the third light-emitting layer 63 preferably has a peak wavelength longer than the peak wavelength of light emitted from the first light-emitting layer 42. The first light-emitting layer 42, the second light-emitting layer 62, and the third light-emitting layer 63 can therefore emit light in a balanced manner.

Although the average thickness of the third light-emitting layer 63 is not specifically limited, the third light-emitting layer 63 has an average thickness that is preferably in the range from 5 to 50 nm, more preferably in the range from 5 to 40 nm, and further preferably 5 to 30 nm. By virtue of such a configuration, the driving voltage of the light-emitting element 1 can be reduced, and the third light-emitting layer 63 can efficiently emit light. In particular, in the case where the second light-emitting layer 62 and the third light-emitting layer 63 are stacked as in this embodiment, the third light-emitting layer 63 is configured so as to have a relatively thin thickness, so that both the second light-emitting layer 62 and the third light-emitting layer 63 are positioned in a recombination region in which holes and electrons recombine, thereby emitting light from these layers in a balanced manner.

In this embodiment, although an example in which the second light emitter 6 includes the two light-emitting layers (namely, the second light-emitting layer 62 and the third light-emitting layer 63) has been described, the second light emitter 6 may have a single light-emitting layer. In other words, in the second light emitter 6, any one of the second light-emitting layer 62 and the third light-emitting layer 63 may not be provided. Furthermore, the second light emitter 6 may include three or more light-emitting layers. In other words, the second light emitter 6 may have at least one light-emitting layer in addition to the second light-emitting layer 62 and the third light-emitting layer 63. Furthermore, in the case where the second light emitter 6 includes a plurality of light-emitting layers, the light-emitting layers may individually emit light beams of the same or different colors. Moreover, in the case where the second light emitter 6 includes a plurality of light-emitting layers, an intermediate layer may be provided between the light-emitting layers.

### Hole-Blocking Layer

The hole-blocking layer 64 has a function to block holes. Holes are therefore prevented from being transported from the third light-emitting layer 63 to the electron transport layer 65. The electron transport layer 65 can be accordingly prevented from being inversely affected by holes. In addition, the hole-blocking layer 64 has a function to transport electrons. Electrons transported through the electron transport layer 65 which will be hereinafter described can be accordingly transported to the third light-emitting layer 63.

Examples of a material of the hole-blocking layer 64 include carbazole derivatives such as 3-phenyl-4-(1′-naphthyl)-5-phenylcarbazole and 4,4′-N,N′-dicarbazole biphenyl (CBP); phenanthroline derivatives; triazole derivatives; quinolinolato metal complexes such as tris(8-quinolinolato)aluminum (Alq) and bis-(2-methyl-8-quinolinolato)-4-(phenylphenolato)aluminum; carbazolyl group-containing compounds such as N-dicarbazolyl-3,5-benzene, poly(9-vinylcarbazole), 4,4′,4″-tris(9-carbazolyl)triphenylamine, 4,4′-bis(9-carbazolyl)-2,2′-dimethyl biphenyl; and 2,9-dimethyl-4,7-diphenyl-1,10-phenanthroline (BCP). These materials may be alone or in combination of two or more.

Although the average thickness of the hole-blocking layer 64 is not specifically limited, the hole-blocking layer 64 has an average thickness that is preferably in the range from 1 to 50 nm, more preferably in the range from 3 to 30 nm, and further preferably in the range from 5 to 20 nm.

The hole-blocking layer 64 may not be provided depending on the configuration of each of the second light-emitting layer 62, third light-emitting layer 63, and electron transport layer 65.

### Electron Transport Layer

The electron transport layer 65 has a function to transport the electrons to the second light-emitting layer 62, the electrons being injected from the cathode 7 through the electron injection layer 66.

Examples of a material (electron transportable material) of the electron transport layer 65 include quinoline derivatives such as an organometallic complex containing 8-quinolinol or derivatives thereof as a ligand [for example, tris(8-quinolinolato)aluminum complex (ALq₃)], oxadiazole derivatives, perylene derivatives, pyridine derivatives, pyrimidine derivatives, quinoxaline derivatives, diphenylquinone derivatives, and nitro-substituted fluorene derivatives. These materials may be used alone or in combination of two or more.

Although the average thickness of the electron transport layer 65 is not specifically limited, the electron transport layer 65 has an average thickness that is preferably in the range from 10 to 100 nm, more preferably in the range from 10 to 50 nm.

### Electron Injection Layer

The electron injection layer 66 has a function to improve efficiency of injecting electrons from the cathode 7.

Examples of a material (electron-injecting material) of the electron injection layer 66 include various types of inorganic insulating materials and include various types of inorganic semiconductor materials.

Examples of such inorganic insulating materials include alkali metal chalcogenides (oxides, sulfides, selenides, tellurides), alkali earth metal chalcogenides, halides of alkali metals, and halides of alkali earth metals. These materials may be used alone or in combination of two or more. These materials are used as a primary component of the electron injection layer 66, thereby being able to further enhancing electron injection properties. In particular, alkali metal compounds (such as alkali metal chalcogenides and alkali earth metal chalcogenides) each having a significantly low work function are used to form the electron injection layer 66, thereby enabling the light-emitting element 1 to emit light with high luminance.

Examples of the alkali metal chalcogenides include Li₂O, LiO, Na₂S, Na₂Se, and NaO.

Examples of the alkali earth metal chalcogenides include CaO, BaO, SrO, BeO, BaS, MgO, and CaSe.

Examples of the halides of alkali metals include CsF, LiF, NaF, KF, LiCl, KCl, and NaCl.

Examples of the halides of alkali earth metals include CaF₂, BaF₂, SrF₂, MgF₂, and BeF₂.

Examples of the inorganic semiconductor materials include oxides, nitrides, and oxynitrides, each containing at least one element selected from Li, Na, Ba, Ca, Sr, Yb, Al, Ga, In, Cd, Mg, Si, Ta, Sb, and Zn. These materials may be used alone or in combination of two or more.

Although the average thickness of the electron injection layer is not specifically limited, the electron injection layer has an average thickness that is preferably in the approximate range from 0.1 to 1000 nm, more preferably in the approximate range from 0.2 to 100 nm, and further preferably in the approximate range from 0.2 to 50 nm.

### Cathode

The cathode 7 injects electrons into the second light emitter 6. A material having a low work function is preferably employed as a material of the cathode 7.

Examples of the material of the cathode 7 include Li, Mg, Ca, Sr, La, Ce, Er, Eu, Sc, Y, Yb, Ag, Cu, Al, Cs, Rb, and an alloy thereof. These materials may be used alone or in combination of two or more (for example, layered structure including several layers).

In particular, in the case where the alloy is used as the material of the cathode 7, an alloy containing a stable metal element such as Ag, Al, or Cu, specifically an alloy such as MgAg, AlLi, or CuLi, is preferably used. Such an alloy is used as the material of the cathode 7, thereby being able to improve the efficiency and stability of electron injection in the cathode 7.

Although the average thickness of the cathode 7 is not specifically limited, the cathode 7 has an average thickness that is preferably in the approximate range from 100 to 400 nm, more preferably in the approximate range from 100 to 200 nm.

The light-emitting element 1 of this embodiment is a bottom emission type, and the cathode 7 may not therefore have specific optical transparency.

### Sealing Member

The sealing member 8 is provided so as to cover the anode 3, the layered structure 15, and the cathode 7 and has a function to seal each component to provide air proof, thereby blocking oxygen and moisture. The sealing member 8 is provided, thereby being able to provide advantageous effects, for example, in which the reliability of the light-emitting element 1 is improved and in which the quality of the light-emitting element 1 is prevented from being degraded and deteriorated (durability is enhanced).

Examples of a material of the sealing member 8 include Al, Au, Cr, Nb, Ta, Ti, or an alloy thereof; silicon oxide; and various resin materials. In the case where an electrically conductive material is used as the material of the sealing member 8, an insulating film is preferably provided between the sealing member 8 and the components including the anode 3, layered structure 15, and cathode 7 in order to prevent short circuit, where appropriate.

Furthermore, in order to obtain sealing, the sealing member 8 may be provided in the form of a plate so as to face the substrate 2, and a sealing material such as a thermosetting resin may be provided therebetween.

In the light-emitting element 1 having such a configuration, voltage is applied between the anode 3 and the cathode 7, thereby generating holes and electrons in the carrier-generating layer 5. The generated electrons are transported to the first light-emitting layer 42 and then recombine with holes injected from the anode 3, thereby contributing to light emission. On the other hands, the generated holes are transported to the second light-emitting layer 62 and the third light-emitting layer 63 and then recombine with electrons injected from the cathode 7, thereby contributing to light emission.

In the light-emitting element 1, accordingly, because the first light-emitting layer 42, second light-emitting layer 62, and third light-emitting layer 63 can each emit light, light emission efficiency can be enhanced, and a driving voltage can be reduced, as compared with a light-emitting element merely having a single light-emitting layer.

In particular, in the light-emitting element 1, the n-type electron transport layer 51 of the carrier-generating layer 5 contacts the first light-emitting layer 42, and the diffusion of the material contained in the n-type electron transport layer 51 (especially, electron donor material hereinafter described) to the layer on the side of the anode 3 (in this embodiment, the first light-emitting layer 42) can be therefore prevented or suppressed. Even in the case where the light-emitting element 1 is continuously driven at a constant current level for long time, the electron transportability and electron injection properties of the re-type electron transport layer 51 can be accordingly prevented from being decreased. The increase of the driving voltage of the light-emitting element 1 can be consequently suppressed.

The light-emitting element 1 described above can be manufactured, for example, through the following processes.

### First Process

First, the substrate 2 is prepared, and the anode 3 is then formed on the substrate 2.

The anode 3 can be formed, for example, by a chemical vapor deposition (CVD) method such as plasma CVD or thermal CVD, a dry plating technique such as vacuum deposition, a wet plating technique such as electrolytic plating, a thermal spraying technique, a sol-gel method, a metal organic deposition (MOD) method, or a bonding technique utilizing metal foil.

### Second Process

The first light emitter 4 is subsequently formed on the anode 3.

The hole transport layer 41 and the first light-emitting layer 42 are formed in sequence so as to overlie the anode 3, thereby being able to form the first light emitter 4.

These layers can be formed, for example, by a gas phase process utilizing a CVD method or a dry plating technique such as vacuum deposition or spattering.

Furthermore, liquid materials are prepared by separately dissolving materials of the individual layers in solvents or dispersing such materials in dispersion media. Subsequently, the resultant materials are respectively applied onto the anode 3 (and a layer to be formed on the anode 3) and then are dried (removing the solvent or dispersing media), thereby also being able to form the first light emitter 4.

Such liquid materials can be applied, for example, by various types of coating techniques such as a spin coating method, a roll coating technique, and an ink jet printing technique. Such coating techniques are used, thereby being able to form the layers included in the first light emitter 4 with relative ease.

Examples of the solvent or dispersion medium used for preparing the liquid materials include various types of inorganic solvents, various types of organic solvents, and a mixed solvent containing these solvents.

The drying is performed, for example, by leaving the product in air pressure or reduced-pressure atmosphere, thermal processing, or inert gas blasting.

Prior to this process, the upper surface of the anode 3 may be subjected to oxygen plasma treatment. By virtue of such treatment, a lyophilic property can be imparted to the upper surface of the anode 3, organic substances adhering to the upper surface of the anode 3 can be removed (cleaned off), and a work function around the upper surface of the anode 3 can be adjusted.

Preferable examples of the conditions in the oxygen plasma treatment include plasma power that is approximately in the range from 100 to 800 W, a gas flow ratio that is approximately in the range from 50 to 100 mL/min, a work piece (anode 3) transportation speed that is approximately in the range from 0.5 to 10 mm/sec, and the temperature of the substrate 2 in the approximate range from 70 to 90° C.

### Third Process

The carrier-generating layer 5 is subsequently formed on the first light emitter 4.

The n-type electron transport layer 51 and the electron-withdrawing layer 52 are formed in sequence so as to overlie the first light emitter 4, thereby being able to form the carrier-generating layer 5.

Each of the layers included in the carrier-generating layer 5 can be formed, for example, by a gas phase process utilizing a CVD method or a dry plating technique such as vacuum deposition or spattering.

Furthermore, materials of the individual layers included in the carrier-generating layer 5 are separately dissolved in solvents or dispersed in dispersion media. Subsequently, the resultant products are respectively applied onto the first light emitter 4 (and a layer to be formed on the first light emitter 4) and then are dried (removing the solvents or dispersing media), thereby also being able to form the carrier-generating layer 5.

### Fourth Process

The second light emitter 6 is subsequently formed on the carrier-generating layer 5.

The second light emitter 6 can be formed in the same manner as employed in the formation of the first light emitter 4.

### Fifth Process

The cathode 7 can be subsequently formed on the second light emitter 6.

The cathode 7 can be formed, for example, by vacuum deposition, a spattering technique, a bonding technique utilizing metal foil, or applying ink of metal particles and then heating the applied ink.

Through these processes, the light-emitting element 1 is produced.

Finally, the sealing member 8 is provided so as to cover the produced light-emitting element 1 and is then bonded to the substrate 2.

The light-emitting element 1 can be applied, for example, to a light-emitting device (light-emitting device of embodiments of the invention).

The light-emitting device includes the light-emitting element 1. The light-emitting device is therefore driven with a relatively low driving voltage and has high light emission efficiency and prolonged emission lifetime. In addition, even in the case of continuous driving at a constant current level, the increase of a driving voltage can be suppressed, and high reliability is therefore provided.

Such a light-emitting device can be used, for example, as a light source or the like used for an illumination lamp or the like.

Furthermore, in the light-emitting device, a plurality of the light-emitting elements are arranged in a matrix, thereby being able to form the light-emitting device used in a display device.

A display will be hereinafter described as an example in which the display device of embodiments of the invention is used.

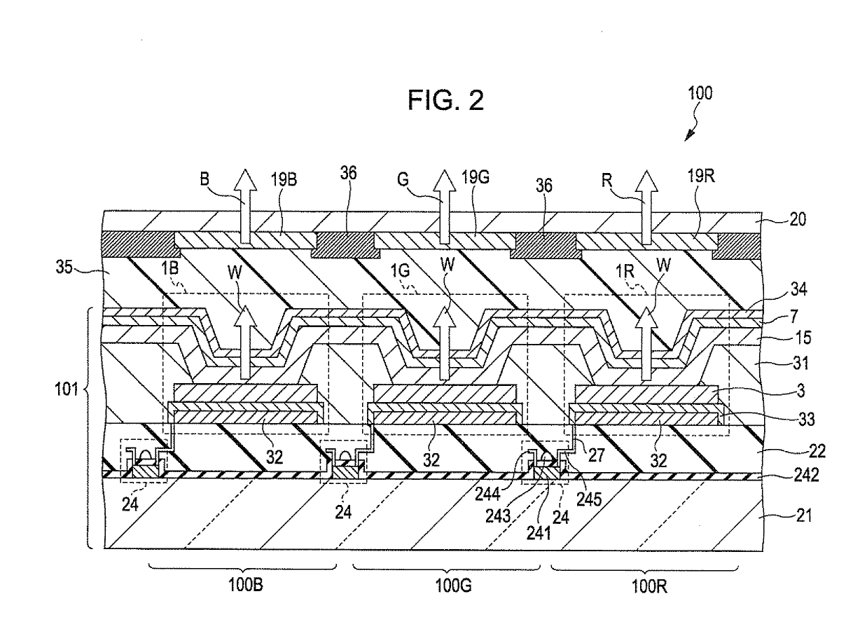

FIG. 2 is a longitudinal sectional view illustrating a display to which the display device of embodiments of the invention is applied.

With reference to FIG. 2, a display 100 has a light-emitting device 101 including a plurality of light-emitting elements 1R, 1G, and 1B which are respectively provided for sub-pixels 100R, 100G, and 100B and has color filters 19R, 19G, and 19B. The display 100 is a display panel having a top emission configuration. In this case, the drive system of the display 100 is not specifically limited, any of an active matrix system and passive matrix system may be employed.

The light-emitting device 101 has a substrate 21, light-emitting elements 1R, 1G, and 1B, and driving transistors 24.

The driving transistors 24 are provided on the substrate 21, and a planarizing layer 22 containing an insulating material is provided so as to cover the driving transistors 24.

Each of the driving transistors 24 includes a semiconductor layer 241 made of silicon, a gate insulating layer 242 formed on the semiconductor layer 241, a gate electrode 243 formed on the gate insulating layer 242, a source electrode 244, and a drain electrode 245.

The light-emitting elements 1R, 1G, and 1B are provided on the planarizing layer 22 so as to correspond to the individual driving transistors 24.

The light-emitting element 1R includes a reflective film 32, an anticorrosive film 33, the anode 3, the layered structure [organic electroluminescence (EL) light emitter] 15, the cathode 7, a cathode cover 34, each being stacked so as to overlie the planarizing layer 22 in sequence. In this embodiment, the anodes 3 of the light-emitting elements 1R, 1G, and 1B function as a pixel electrode and are electrically connected to drain electrodes 245 of the individual driving transistors 24 through conductor portions (wiring lines) 27. The cathodes 7 of the light-emitting elements 1R, 1G, and 1B function as a common electrode.

Each of the light-emitting elements 1G and 1B has a configuration the same as that of the light-emitting element 1R. In FIG. 2, components the same as those illustrated in FIG. 1 are denoted by the same symbols. In the light-emitting elements 1R, 1G, and 1B, the individual reflective films 32 may have different configurations (characteristics) depending on the wavelength of light.

Separating walls 31 are provided between any two of the adjacent light-emitting elements 1R, 1G, and 1B.

An epoxy layer 35 made of an epoxy resin is formed so as to cover the light-emitting device 101 having such a configuration.

The color filters 19R, 19G, and 19B are provided on the epoxy resin layer 35 so as to correspond to the light-emitting elements 1R, 1G, and 1B, respectively.

The color filter 19R converts white light W emitted from the light-emitting element 1R into red light (R). The color filter 19G converts white light W emitted from the light-emitting element 1G into green light (G). The color filter 19B converts white light W emitted from the light-emitting element 1B into blue light (B). The color filters 19R, 19G, and 19B are used in combination with the respective light-emitting elements 1R, 1G, and 1B, thereby being able to display a full-color image.

Light-shielding layers 36 are formed between any two of the adjacent color filters 19R, 19G, and 19B. The light-shielding layers 36 can block unwanted light emitted from the sub-pixels 100R, 100G, and 100B.

A sealing substrate 20 overlies the color filters 19R, 19G, and 19B and the light-shielding layers 36 so as to cover these components.

The display 100 described above may be formed as a monochrome display or as a color display which is enabled by selecting light-emitting materials of the individual light-emitting elements 1R, 1G, and 1B without the color filters.

Because the display 100 (display device of embodiments of the invention) includes the light-emitting device described above, the display 100 is driven at a relatively low voltage, has excellent durability (prolonged emission lifetime), and has excellent light emission efficiency. A high-quality image can be accordingly displayed for a long period with low power consumption. In particular, even in the case of continuous driving at a constant current level, the increase of a driving voltage can be suppressed. Stable driving is therefore enabled, and excellent reliability can be exhibited.

The display 100 (display device of embodiments of the invention) can be incorporated with various types of electronic apparatus. Because such electronic apparatus includes the display device described above, excellent durability can be exhibited, light emission efficiency can be enhanced, and a driving voltage can be reduced. A high-quality image can be accordingly displayed for a long period, and excellent reliability can be exhibited.

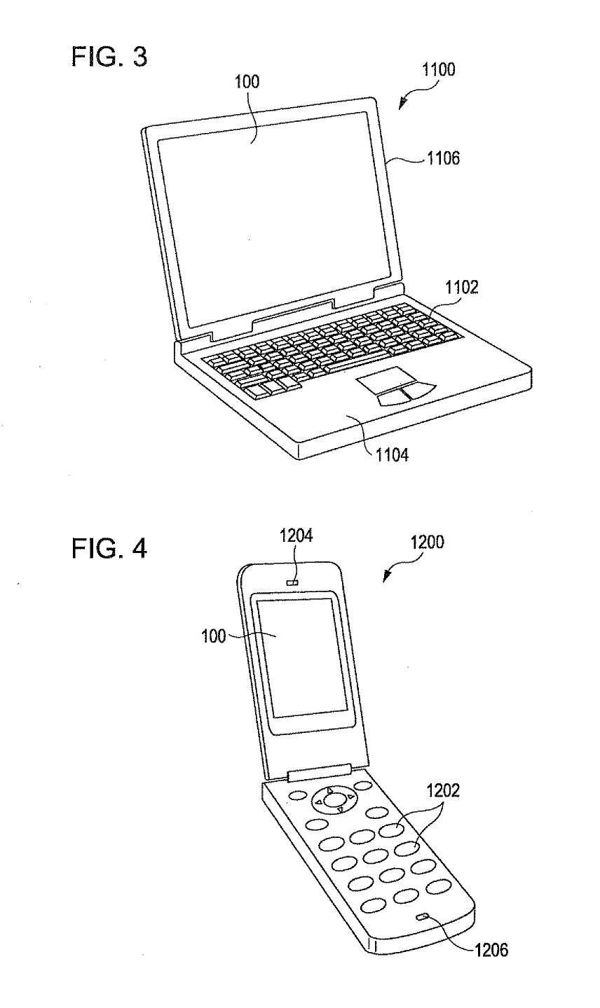

FIG. 3 is a perspective view illustrating the configuration of a mobile (or laptop) personal computer to which an electronic apparatus of embodiments of the invention is applied.

With reference to FIG. 3, a personal computer 1100 includes a main body 1104 having a keyboard 1102 and includes a display unit 1106 having a display section. The display unit 1106 is supported by the main body 1104 so as to be able to rotate around a hinge structure.

In the personal computer 1100, the display section of the display unit 1106 includes the display 100 described above.

FIG. 4 is a perspective view illustrating the configuration of a mobile phone [including Personal Handyphone System (PHS)] to which the electronic apparatus of embodiments of the invention is applied.

With reference to FIG. 4, the mobile phone 1200 includes a plurality of operating buttons 1202, an earpiece 1204, a mouthpiece 1206, and a display section.

In the mobile phone 1200, the display section includes the display 100.

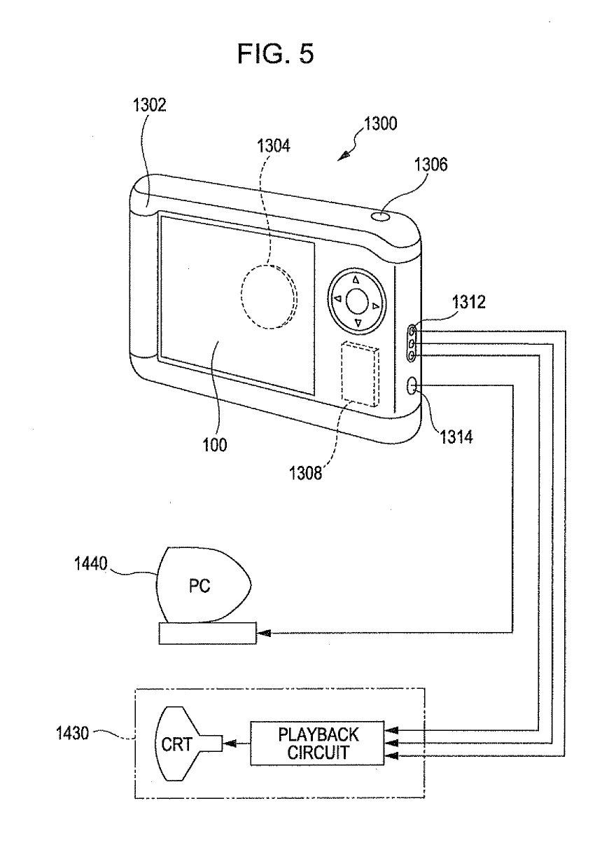

FIG. 5 is a perspective view illustrating the configuration of a digital still camera to which the electronic apparatus of embodiments of the invention is applied. FIG. 5 further illustrates connection to external apparatuses in a brief manner.

In a normal camera, a silver-salt photographic film is exposed to light on the basis of an optical image of a subject. On the other hand, in a digital still camera 1300, an optical image of a subject is photoelectrically converted to an imaging signal (picture signal) by an imaging device such as a charge-coupled device (CCD).

In the digital still camera 1300, a display section is provided on the back surface of a case (body) 1302. The display section displays an image on the basis of the imaging signal generated by the CCD. The display section functions as a viewfinder that displays a subject as a digital image.

In the digital still camera 1300, the display section includes the display 100.

The circuit board 1308 is provided inside the case 1302. The circuit board 1308 has a memory device in which the imaging signal can be stored (recorded).

A light-receiving unit 1304 is provided on the front surface (depth side in FIG. 5) of the case 1302, the light-receiving unit 1304 including an optical lens (imaging optical system) and the CCD.

In the case where users press a shutter button 1306 while seeing a subject image displayed on the display section, the imaging signal generated by the CCD at that time is transmitted to and stored in the memory device of the circuit board 1308.

In the digital still camera 1300, video-signal output terminals 1312 and a data-communication input-output terminal 1314 are provided on a side surface of the case 1302. With reference to FIG. 5, the video-signal output terminals 1312 are appropriately connected to a monitor 1430, and the data-communication input-output terminal 1314 is appropriately connected to a personal computer 1440. The imaging signal stored in the memory device of the circuit board 1308 can be output to the monitor 1430 and the personal computer 1440 with a predetermined manipulation.

In addition to the personal computer (mobile personal computer) illustrated in FIG. 3, the mobile phone illustrated in FIG. 4, and the digital still camera illustrated in FIG. 5, the electronic apparatus of embodiments of the invention can be applied to, for example, a television set, a video camcorder, a viewfinder- or monitor-equipped camcorder, a laptop personal computer, a car navigation system, a pager, an electronic organizer (with or without a communication facility), an electronic dictionary, a calculator, an electronic game machine, a word processor, a workstation, a video phone, a security monitor, electronic binoculars, a point of sale (POS) terminal, equipment having a touch panel (such as a cash dispenser of a financial institution or an automatic ticket machine), a medical equipment (such as an electronic thermometer, a sphygmomanometer, a blood glucose meter, an electrocardiograph display, medical ultrasound equipment, and an endoscope display), a fish finder, a variety of measurement equipment, a variety of instruments (such as those used for cars, aircrafts, and ships), a flight simulator, a variety of other monitors, and a projection type display such as a projector.

Although the light-emitting element, light-emitting device, display device, and electronic apparatus of embodiments of the invention have been described on the basis of the above embodiments with reference to the accompanying drawings, embodiments of the invention are not limited to the above embodiments.

Although the light-emitting element has the three light-emitting layer as described above, embodiments of the invention are not limited to such a configuration. The light-emitting element, for example, may have two light-emitting layers or may have four or more light-emitting layers. In this case, at least one light-emitting layer may be provided on each of the one and opposite sides of the carrier-generating layer.

Furthermore, in the light-emitting element, although the light emitters (light-emitting units) have layers other than the light-emitting layer (for example, hole transport layer and electron transport layer) as described above, embodiments of the invention are not limited to such a configuration. The light emitters may have at least one light-emitting layer and may be formed, for example, so as to only include light-emitting layer.

### EXAMPLE

Examples of embodiments of the invention will be specifically described.

### 1. Manufacturing Light-Emitting Element

### Example 1

### First Process

A transparent glass substrate having an average thickness of 0.5 mm was prepared. An ITO electrode (anode) was formed on the substrate by a spattering technique so as to have an average thickness of 50 nm.

The substrate was dipped in acetone and 2-propanol in sequence and was then subjected to ultrasonic cleaning.

The resultant product was then subjected to oxygen plasma treatment.

### Second Process

Subsequently, N,N′-di(1-naphthyl)-N,N′-diphenyl-1,1′-biphenyl-4,4′-diamine (NPD) was deposited on the ITO electrode by a vacuum deposition method, thereby forming a hole transport layer (hole transport layer of a first light emitter) having an average thickness of 50 nm.

### Third Process

A first light-emitting layer was subsequently formed on the hole transport layer by a vacuum deposition method so as to have an average thickness of 30 nm.

In this case, a mixed material of BD102 (commercially available from Idemitsu Kosan Co., Ltd.) as a blue light-emitting material (guest material) and BH215 (commercially available from Idemitsu Kosan Co., Ltd.) as a host material was used as a material of the first light-emitting layer. The blue light-emitting material was contained in the first light-emitting layer in an amount (dopant concentration) of 5.0 weight %.

### Fourth Process

Subsequently, tris(8-quinolinolato)aluminum (Alq₃) and Li₂O were deposited on the first light-emitting layer by a vacuum deposition method, thereby forming an n-type electron transport layer (n-type electron transport layer of a carrier-generating layer) having an average thickness of 40 nm. In this case, tris(8-quinolinolato)aluminum (Alq₃) and Li₂O were contained in the n-type electron transport layer at a volume ratio of 96:4.

### Fifth Process

Subsequently, hexacyanohexaazatriphenylene was deposited on the n-type electron transport layer by a vacuum deposition method, thereby forming an electron-withdrawing layer having an average thickness of 20 nm. Through the fourth and fifth processes, the carrier-generating layer including the n-type electron transport layer and electron-withdrawing layer was formed.

### Sixth Process

Subsequently, N,N′-di(1-naphthyl)-N,N′-diphenyl-1,1′-biphenyl-4,4′-diamine (NPD) was deposited on the carrier-generating layer (electron-withdrawing layer) by a vacuum deposition method, thereby forming a hole transport layer having an average thickness of 20 nm.

### Seventh Process

A second light-emitting layer was subsequently formed on the hole transport layer by a vacuum deposition method so as to have an average thickness of 10 nm.

In this case, a mixed material of Ir(piq)₃ as a red light-emitting material (guest material) and CBP as a host material was used as a material of the second light-emitting layer. The red light-emitting material was contained in the second light-emitting layer in an amount (dopant concentration) of 10.0 weight %.

### Eighth Process

A third light-emitting layer was subsequently formed on the second light-emitting layer by a vacuum deposition method so as to have an average thickness of 10 nm.

In this case, a mixed material of Ir(ppy)₃ as a green light-emitting material (guest material) and CBP as a host material was used as a material of the third light-emitting layer. The green light-emitting material was contained in the third light-emitting layer in an amount (dopant concentration) of 10.0 weight %.

### Ninth Process

Subsequently, BCP as a carbazole derivative was deposited on the third light-emitting layer by a vapor deposition method, thereby forming a hole-blocking layer having an average thickness of 10 nm.

### Tenth Process

Subsequently, tris(8-quinolinolato)aluminum (Alq₃) was deposited on the hole-blocking layer by a vacuum deposition method, thereby forming an electron transport layer (electron transport layer of a second light emitter) having an average thickness of 30 nm.

### Eleventh Process

Subsequently, lithium fluoride (LiF) was deposited on the electron transport layer by a vacuum deposition method, thereby forming an electron injection layer having an average thickness of 1.0 nm.

### Twelfth Process

Subsequently, Al was deposited on the electron injection layer by a vacuum deposition method, thereby forming a cathode having an average thickness of 100 nm.

### Thirteenth Process

A protective cover (sealing member) made of glass was provided so as to cover the formed layers and was then fixed by using an epoxy resin to provide sealing.

Through these processes, a light-emitting element (tandem-type light-emitting element) was manufactured, in which the anode, hole transport layer, first light-emitting layer, carrier-generating layer (n-type electron transport layer and electron-withdrawing layer), hole transport layer, second light-emitting layer, third light-emitting layer, hole-blocking layer, electron transport layer, electron injection layer, and cathode were stacked in sequence so as to overlie the substrate.

### Example 2

The process configurations the same as those in the example 1 were employed except that the first light-emitting layer was formed so as to have an average thickness of 45 nm and except that the n-type electron transport layer of the carrier-generating layer was formed so as to have an average thickness of 25 nm, thereby manufacturing a light-emitting element.

### Example 3

The process configurations the same as those in the example 1 were employed except that the first light-emitting layer was formed so as to have an average thickness of 65 nm and except that the n-type electron transport layer of the carrier-generating layer was formed so as to have an average thickness of 5 nm, thereby manufacturing a light-emitting element.

### Example 4

In the formation of the n-type electron transport layer of the carrier-generating layer, Li (simple alkali metal) was used in place of LiO₂ (alkali metal compound). In addition, the first light-emitting layer was formed so as to have an average thickness of 45 nm, and the n-type electron transport layer of the carrier-generating layer was formed so as to have an average thickness of 25 nm. Except these changes, the process configurations the same as those in the example 1 were employed, thereby forming a light-emitting element.

### Example 5

In the formation of the n-type electron transport layer of the carrier-generating layer, the concentration of LiO₂ was increased from the side of the anode to the side of the cathode. In addition, the first light-emitting layer was formed so as to have an average thickness of 45 nm, and the n-type electron transport layer of the carrier-generating layer was formed so as to have an average thickness of 25 nm. Except these changes, the process configurations the same as those in the example 1 were employed, thereby forming a light-emitting element.

In this case, the light-emitting element was formed so as to have a LiO₂ concentration of 2 volume % in the vicinity of the interface between the n-type electron transport layer of the carrier-generating layer and the first light-emitting layer and so as to have a LiO₂ concentration of 5 volume % in the vicinity of the interface between the n-type electron transport layer and the electron-withdrawing layer of the carrier-generating layer.

### Comparison Example

An electron transport layer was formed between the first light-emitting layer and the n-type electron transport layer of the carrier-generating layer, thereby preventing the contact of the first light-emitting layer with the re-type electron transport layer. Except this change, the process configurations the same as those in the example 1 were employed, thereby forming a light-emitting element.

Tris(8-quinolinolato)aluminum (Alq₃) was deposited by a vacuum deposition method, thereby forming the electron transport layer having an average thickness of 20 nm between the first light-emitting layer and the n-type electron transport layer of the carrier-generating layer.

### 2. Evaluation

### 2-1. Evaluation of Light Emission Efficiency

In each of the examples and the comparison example, a direct-current power source was used to apply a constant current of 100 mA/cm² to the light-emitting element. During the application, external quantum efficiency was measured.

### 2-2. Evaluation of Emission Lifetime

In each of the examples and the comparison example, a direct-current power source was used to continuously apply a constant current of 100 mA/cm² to the light-emitting element. During the application, a luminance meter was used to measure luminance, thereby obtaining a time period (LT80) which was taken to decrease the luminance to 80% magnitude of the initial luminance.

### 2-3. Evaluation of Increase of Voltage

In each of the examples and the comparison example, a direct-current power source was used to continuously apply a constant current of 100 mA/cm² to the light-emitting element for 500 hours. During the application, a driving voltage was measured to obtain the difference between the initial driving voltage and the voltage after the driving for 500 hours (increased amount of voltage).

Evaluation results were listed in Table 1. In Table 1, the values of external quantum efficiency and lifetime were standardized on the basis of the values of those in the comparison example.

TABLE 1

| | | | Presence or | | | | |
|---|---|---|---|---|---|---|---|
| | | | absence of electron | | | | |
| | | | transport layer | | Evaluation | | |
| | Carrier-generating layer | | (between carrier- | Average thickness | External | | |
| | Material of | Average | generating layer | of first light- | quantum | | Increase of |
| | n-type electron | thickness | and first light- | emitting layer | efficiency | | driving voltage |
| | transport layer | [nm] | emitting layer) | [nm] | [%] | Lifetime | [V] |
| Example 1 | Alq₃ + Li₂0 | 40 | Absence | 30 | 0.88 | 0.80 | +0.4 |
| Example 2 | Alq₃ + Li₂0 | 25 | Absence | 45 | 0.99 | 1.01 | +0.4 |
| Example 3 | Alq₃ + Li₂0 | 5 | Absence | 65 | 1.01 | 0.95 | +0.5 |
| Example 4 | Alq₃ + Li | 25 | Absence | 45 | 1.01 | 1.01 | +0.4 |
| Example 5 | Alq₃ + Li₂0 | 25 | Absence | 45 | 1.05 | 1.05 | +0.5 |
| | (Concentration | | | | | | |
| | gradient) | | | | | | |
| Comparison | Alq₃ + Li₂0 | 20 | Presence | 30 | 1.00 | 1.00 | +0.9 |
| example | | | | | | | |

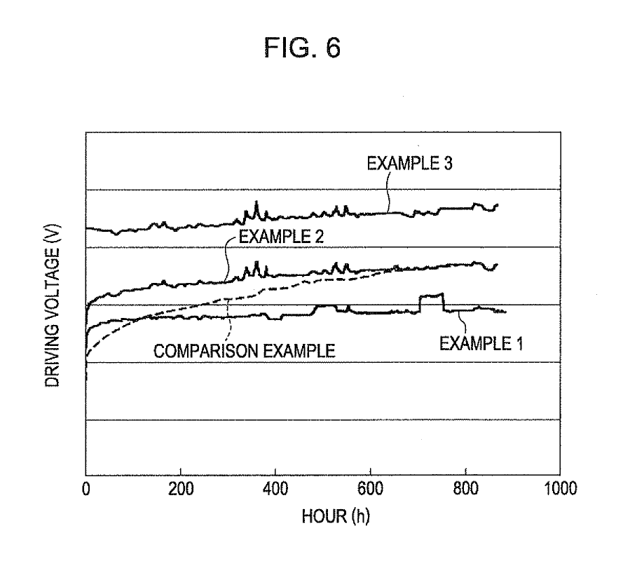

In each of the examples 1 to 3 and the comparison example, a direct-current power source was used to continuously apply a constant current of 100 mA/cm² to the light-emitting element for 800 hours. During the application, a driving voltage was measured. FIG. 6 is a graph illustrating variation in the driving voltage.

As is obvious from Table 1, in the light-emitting element of each of the examples, the increase of voltage could be suppressed in continuous driving while excellent external quantum efficiency and prolonged lifetime which were equivalent to those of the light-emitting element in the comparison example were secured.

The entire disclosure of Japanese Patent Application No. 2010-176636, filed Aug. 5, 2010 is expressly incorporated by reference herein.

What is claimed is:

1. A light-emitting element comprising:
an anode;
a cathode;
a first light-emitting layer that is disposed between the anode and the cathode, the first light-emitting layer emitting light in response to application of voltage between the anode and the cathode;
a second light-emitting layer that is disposed between the cathode and the first light-emitting layer, the second light-emitting layer emitting light in response to application of voltage between the anode and the cathode; and
a carrier-generating layer that is disposed between the first light-emitting layer and the second light-emitting layer, the carrier-generating layer generating electrons and holes, wherein
the carrier-generating layer has an n-type electron transport layer and an electron-withdrawing layer, the n-type electron transport layer contacting the first light-emitting layer and having electron transportability, and the electron-withdrawing layer being disposed between the n-type electron transport layer and the second light-emitting layer and having electron-withdrawing properties.

2. The light-emitting element according to claim 1, wherein the first light-emitting layer has an average thickness that is in the range from 30 to 100 nm.

3. The light-emitting element according to claim 1, wherein the n-type electron transport layer is formed by using a mixed material containing an electron transportable material and an electron donor material.

4. The light-emitting element according to claim 3, wherein the concentration of the electron donor material contained in the n-type electron transport layer is gradually decreased from the side of the cathode to the side of the anode.

5. The light-emitting element according to claim 3, wherein the electron donor material contains at least one of alkali metal, alkali earth metal, an alkali metal compound, and an alkali earth metal compound.

6. The light-emitting element according to claim 1, wherein the first light-emitting layer contains a light-emitting material that generates fluorescence in response to application of voltage between the anode and the cathode.

7. The light-emitting element according to claim 6, wherein the second light-emitting layer contains a light-emitting material that generates phosphorescence in response to application of voltage between the anode and the cathode.

8. The light-emitting element according to claim 6, wherein the second light-emitting layer emits light having a peak wavelength longer than the peak wavelength of light emitted from the first light-emitting layer.

9. The light-emitting element according to claim 1, further comprising a third light-emitting layer that is disposed between the second light-emitting layer and the cathode, the third light-emitting layer emitting light in response to application of voltage between the anode and the cathode.

10. The light-emitting element according to claim 9, wherein the third light-emitting layer contains a light-emitting material that generates phosphorescence in response to application of voltage between the anode and the cathode.

11. The light-emitting element according to claim 10, wherein the third light-emitting layer emits light having a peak wavelength longer than the peak wavelength of light emitted from the first light-emitting layer.

12. The light-emitting element according to claim 1, wherein the electron-withdrawing layer contains organic cyanide having an aromatic ring.

13. The light-emitting element according to claim 12, wherein the organic cyanide is a hexaazatriphenylene derivative.

14. A light-emitting device comprising the light-emitting element according to claim 1.

15. A light-emitting device comprising the light-emitting element according to claim 2.

16. A light-emitting device comprising the light-emitting element according to claim 3.

17. A light-emitting device comprising the light-emitting element according to claim 4.

18. A light-emitting device comprising the light-emitting element according to claim 5.

19. A display device comprising the light-emitting device according to claim 14.

20. An electronic apparatus comprising the display device according to claim 19.
